(19) United States
(12) Patent Application Publication
(10) Pub. No.: US 2026/0360962 A1
(43) Pub. Date: Nov. 12, 2026

(54) RADIO FREQUENCY AIR COIL AND ELECTRICAL CIRCUIT

(71) Applicant: Rohde & Schwarz GmbH & Co. KG, Muenchen (DE)

(72) Inventor: Dirk FEHSE, Muenchen (DE)

(21) Appl. No.: 19/273,774

(22) Filed: Jul. 18, 2025

Related U.S. Application Data
(63) Continuation-in-part of application No. 19/202,931, filed on May 8, 2025.

(51) Int. Cl. H01Q 1/02; H05K 7/20

(52) U.S. Cl. CPC H01Q 1/02; H05K 7/20272

(57) ABSTRACT

A RF air coil including a first hollow conductor and a second hollow conductor each including an electrically conductive material. The first hollow conductor and the second hollow conductor form at least one winding of the RF air coil. The first hollow conductor has a first end portion and a second end portion. The second hollow conductor has a first end portion arranged adjacent to the first end portion of the first hollow conductor and a second end portion arranged adjacent to the second end portion of the first hollow conductor. The RF air coil has a first fluid port that is fluidly connected to the first hollow conductor and a second fluid port that is fluidly connected to the second hollow conductor, such that a liquid cooling agent can flow through the first fluid port, the first hollow conductor, the second hollow conductor, and the second fluid port.

### CROSS-REFERENCE(S) TO RELATED APPLICATION(S)

This application is a continuation-in-part of U.S. application Ser. No. 19/202,931, filed on May 8, 2025.

### FIELD OF THE DISCLOSURE

Embodiments of the present disclosure generally relate to a radio frequency (RF) air coil. Embodiments of the present disclosure further relate to an electrical circuit with an RF air coil system.

### BACKGROUND

Radio frequency (RF) air coils are essential components in RF circuits, particularly for transforming RF power from low voltage levels to high voltage levels in the kilovolt range.

During operation, RF air coils exhibit power losses that result in substantial heat generation. To maintain proper operation and prevent component failure, effective cooling systems are required. Liquid cooling has proven to be the most effective method for dissipating this heat.

Conventional cooling approaches may employ a tube-within-tube configuration, where cooling medium flows through an outer tube and returns through an inner tube or hose of smaller diameter. However, this arrangement suffers from several technical limitations. The returning heated cooling medium transfers heat to the incoming cooler medium, reducing overall cooling effectiveness. Additionally, the inner tube rarely maintains a centered position within the outer tube, creating turbulence that causes uncontrollable pressure drops and impedes flow rates.

These flow restrictions are further exacerbated by regulatory requirements for pressure vessel compliance, which mandate thicker wall construction for the inner tube, thereby reducing the available cross sectional area for cooling medium flow. The resulting larger coil diameters required to accommodate the inner tube create manufacturing challenges and increase space requirements in RF equipment, while also negatively affecting coil inductance due to proximity effects with metallic enclosure walls.

Thus, there is a need for an RF air coil cooling system that provides improved thermal efficiency und enhanced flow properties.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a radio frequency air coil. In an embodiment, the air coil comprises a first hollow conductor and a second hollow conductor, each comprising an electrically conductive material. The first hollow conductor and the second hollow conductor form at least one winding of the RF air coil. The first hollow conductor has a first end portion and a second end portion. The second hollow conductor has a first end portion that is arranged adjacent to the first end portion of the first hollow conductor. The second hollow conductor has a second end portion that is arranged adjacent to the second end portion of the first hollow conductor. The RF air coil has a first fluid port that is fluidly connected to the first hollow conductor and a second fluid port that is fluidly connected to the second hollow conductor, such that a liquid cooling agent can flow through the first fluid port, the first hollow conductor, the second hollow conductor, and the second fluid port. The first hollow conductor and the second hollow conductor provide two separate fluid path portions for the liquid cooling agent. The first fluid port is arranged at the first end portion of the first hollow conductor and the second fluid port is arranged at the first end portion of the second hollow conductor.

Generally, the RF air coil according to embodiments of the present technology is a liquid-cooled RF air coil with a dual hollow conductor configuration.

Generally, this dual hollow conductor configuration provides significant thermal efficiency improvements by preventing heat transfer between incoming and outgoing cooling medium. Unlike conventional tube-within-tube designs where the returning heated cooling medium transfers heat to the incoming cooler medium, the separate fluid path portions maintain optimal cooling efficiency throughout the coil operation.

This configuration eliminates flow turbulence and uncontrollable pressure drops that plague conventional systems where inner tubes create chaotic flow patterns. By providing two separate, uniform cross sectional paths, the cooling medium flows smoothly without obstruction, maintaining consistent pressure drop characteristics and enabling higher flow rates for enhanced heat dissipation.

This design also maximizes available cross sectional area for cooling medium flow by eliminating the need for an inner tube or hose that reduces flow capacity. This increased flow area, combined with the absence of turbulence, significantly reduces the required back-pressure for the cooling system, improving overall thermal management efficiency.

Further, the compact design enables smaller coil diameters compared to conventional systems that require oversized tubes to accommodate inner cooling passages. This space efficiency reduces manufacturing complexity, minimizes equipment footprint, and improves coil inductance by allowing closer proximity to metallic enclosure walls without compromising electrical performance.

It is emphasized that the first hollow conductor and the second hollow conductor are formed as two separate parts, rather than a single hollow conductor being bent back upon itself.

Thus, the fluid path portions provided by the hollow conductors are structurally separate, i.e. the fluid path portions provided by the first hollow conductor and the second hollow conductor do not merge into each other immediately.

According to an embodiment of the present disclosure, the electrically conductive material comprises at least one electrically conductive metal, providing excellent electrical conductivity for RF applications while maintaining structural integrity for the hollow conductor design.

According to another embodiment of the present disclosure, the at least one electrically conductive metal comprises copper, which offers superior electrical conductivity and thermal properties, making it ideal for high-frequency applications and efficient heat dissipation.

According to an aspect of the present disclosure, the at least one electrically conductive material comprises, for example, at least one electrically conductive non-metallic material, allowing for alternative conductor materials that may provide specific advantages such as reduced weight or improved corrosion resistance.

According to an embodiment of the present disclosure, the electrically conductive material is arranged at a radially outer portion of the hollow conductors, ensuring that the RF inductance is primarily generated by the outer surface while maintaining the hollow interior for cooling medium flow.

According to another aspect of the present disclosure, the RF air coil comprises, for example, a redirecting portion that fluidly connects the second end portion of the first hollow conductor with the second end portion of the second hollow conductor, enabling continuous flow of cooling medium through both conductors while providing a 180-degree flow redirection at the coil end.

According to another example embodiment of the present disclosure, the redirecting portion is formed separately from the first hollow conductor and the second hollow conductor, providing a modular design that facilitates manufacturing and assembly while allowing for different materials or configurations for the redirecting portion.

According to an embodiment of the present disclosure, the redirecting portion comprises a housing being formed separately from the first hollow conductor and the second hollow conductor, providing space efficiency through integration with the housing and enabling dual functionality including electrical contact capability.

According to an aspect of the present disclosure, the redirecting portion comprises, for example, a tube that is separate from the hollow conductors, allowing for optimal material selection and easier connection to the hollow conductors while maintaining fluid flow continuity.

According to another aspect of the present disclosure, at least the portions of the first hollow conductor and the second hollow conductor forming the at least one winding extend, for example, directly adjacent to each other, ensuring optimal inductivity of the RF air coil while maintaining separate cooling paths.

According to an embodiment of the present disclosure, a cross section of the first hollow conductor is constant at least piecewise, and/or a cross section of the second hollow conductor is constant at least piecewise, eliminating flow turbulence and maintaining consistent pressure drop characteristics throughout the cooling system, for example throughout the RF air coil.

According to another aspect of the present disclosure, the RF air coil comprises, for example, at least one first electrical contact for the first end portions, providing reliable electrical connection for an RF circuit while accommodating the cooling system integration.

In an embodiment, the at least one first electrical contact may be associated with a low-voltage side of the RF circuit, i.e. with a side of the RF circuit having lower potential difference to a reference potential, such as a ground potential.

In an embodiment, the first fluid port, the second fluid port, and the at least one first electrical contact are all arranged at the side of the RF air coil having lower potential (difference to the reference potential), thereby reducing the risk of insulation issues.

Put differently, the RF air coil according to one or more embodiments of the present technology establishes an electrical two-gate and a fluid two-gate, wherein both gates of the fluid two-gate are arranged on the same side of the electrical two-gate, namely at a first electrical gate of the electrical two-gate. The other side of the electrical two-gate, namely the side of a second electrical gate, is free from fluid gates.

In an embodiment, the RF air coil comprises at least one second electrical contact for the second end portions, completing the electrical circuit path while maintaining separation from the cooling system connections.

In an embodiment, the second electrical contact may be associated with a high-voltage side of the RF circuit, i.e. with a side of the RF circuit having higher potential difference to the reference potential.

In an embodiment, the second electrical contact may be established by the redirecting portion described above, for example by a housing of the redirecting portion.

In an embodiment, the inner surfaces of walls of the hollow conductors each comprise a protective layer, preventing corrosion and contamination of the cooling medium while protecting the conductor material from chemical degradation.

This allows, for example, to use liquid cooling agents that would otherwise corrode metals such as copper, for example deionized water.

In one or more embodiments, the protective layer comprises at least one of plastic, stainless steel, or lacquer, providing excellent chemical resistance and durability for long-term operation with various cooling media such as deionized water.

Embodiments of the present disclosure further provide an electrical circuit system comprising an electrical circuit and an RF air coil system. In an embodiment, the RF air coil system comprises an RF air coil, a heat sink, a first cooling agent tube, and a second cooling agent tube. The first cooling agent tube is connected to the first fluid port, and the second cooling agent tube is connected to the second fluid port. At least one of the first cooling agent tube or the second cooling agent tube is directly connected to the heat sink.

The term “electrically connect” is understood to denote that a direct connection via an electrical conductor is established.

The cooling system according to the present technology provides efficient heat removal from the RF air coil while maintaining electrical isolation and optimal thermal management. The direct connection to the heat sink ensures rapid heat dissipation from the cooling medium, maintaining low operating temperatures throughout the RF air coil.

The system architecture enables flexible cooling configurations, allowing for optimized thermal management based on specific application requirements and heat load distributions.

In an embodiment, the first cooling agent tube and the second cooling agent tube each comprise or consist essentially of an electrically isolating material at least partially, preventing unwanted electrical coupling between the cooling system and the electrical circuit, ensuring safe operation and preventing interference.

In an embodiment, the RF air coil system further comprises at least one electrical isolator, wherein the at least one electrical isolator is configured to electrically isolate the hollow conductors from the heat sink, preventing electrical interference and ensuring that the cooling system does not affect the RF performance of the coil.

In an embodiment, the electrical circuit is at least one of an oscillating circuit, an impedance matching circuit, an RF filter circuit, an RF antenna circuit, or an RF frontend circuit, with these applications benefiting from the improved cooling efficiency and compact design enabled by the dual hollow conductor configuration.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows an electrical circuit system with an RF air coil system according to an embodiment of the present disclosure;

FIG. 2 shows a perspective view of a portion of the electrical circuit of FIG. 1;

FIG. 3 shows a cross section through a middle portion of the RF air coil according to an embodiment of the present disclosure; and

FIG. 4 shows a cross section through an end portion of the RF air coil according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

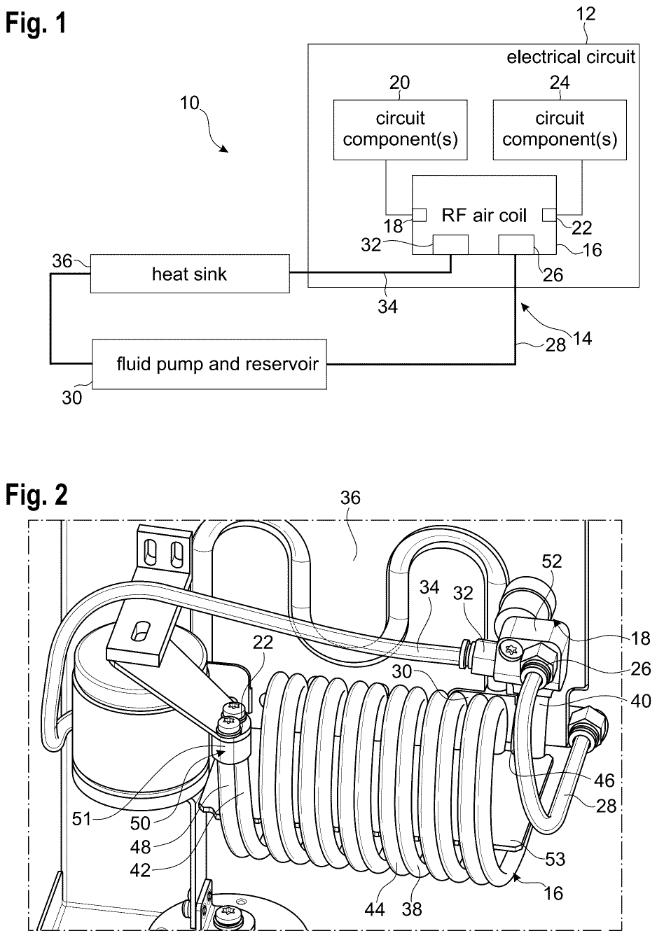

FIG. 1 schematically shows an example of an electrical circuit system 10. The electrical circuit system 10 comprises an electrical circuit 12 and an RF air coil system 14 with a liquid-cooled RF air coil 16 that is integrated into the electrical circuit 12.

In the embodiment of FIG. 1, the RF air coil 16 comprises at least one first electrical contact 18 that is electrically connected to low-side circuit component(s) 20 of the electrical circuit 12. The RF air coil 16 further comprises at least one second electrical contact 22 that is electrically connected to high-side circuit component(s) 24 of the electrical circuit 12. Therein, the terms “low-side” and “high-side” refer to voltages with respect to a reference potential, such as a ground potential. Thus, the low-side circuit component(s) 20 have a smaller potential difference to the reference potential than the high-side circuit component(s) 24.

In an embodiment, the RF air coil 16 may transform RF power from low voltage levels, for example of the order of 10 or 100 volts, at the low-side circuit component(s) 20 to high voltage levels, for example in the kilovolt range, at the high-side circuit component(s) 24.

In one or more embodiments, the electrical circuit 12 may be configured as various types of RF circuits, including but not limited to oscillating circuits, impedance matching circuits, for example impedance matching circuits for plasma heating purposes, RF filter circuits, RF antenna circuits, or RF frontend circuits.

Depending on the application, the circuit components 20, 24 may be chosen appropriately.

In an embodiment, the RF air coil 16 includes a first fluid port 26 that provides a fluid connection for a liquid cooling system. The first fluid port 26 is fluidly connected to a first cooling agent tube 28, which is in turn connected to a fluid pump and reservoir 30. The fluid pump and reservoir 30 provides the driving force for circulating the liquid cooling agent through the RF air coil 16 for effective heat removal.

In an embodiment, the RF air coil 16 also includes a second fluid port 32 that is fluidly connected to a second cooling agent tube 34. The second cooling agent tube 34 is connected to a heat sink 36 that provides heat dissipation from the circulated cooling agent. The heat sink 36 may comprise fins, channels, or other heat dissipation structures to maximize heat transfer to the surrounding environment.

For example, the heat sink 36 may be integrated into a device, such as an RF signal generator. Thus, no extra heat sink may be necessary for cooling the RF air coil 16. Alternatively, a dedicated heat sink may be provided for cooling the liquid cooling agent flowing through the RF air coil 16.

In an embodiment, the heat sink 36 is connected to the fluid pump and reservoir 30, such that the liquid cooling agent cooled down by the heat sink 36 is directed back to the fluid pump and reservoir 30.

In an embodiment, the first cooling agent tube 28 and the second cooling agent tube 34 may each comprise or consist essentially of an electrically isolating material at least partially. Thus, the hollow conductors 38, 44 are electrically isolated from the heat sink 36 and from the fluid pump and reservoir 30, such that unwanted currents and/or voltages between the hollow conductors 38, 44 and the heat sink 36 as well as the fluid pump and reservoir 30 are prevented.

In an embodiment, the cooling agent tubes 28, 34 may comprise or consist (essentially) of any suitable material being electrically insulating and thermally stable in temperature regions reached by the cooling agent during operation. For example, the cooling agent tubes may comprise or consist of plastic, such as PEEK, PEK, PPS, PI, PEI, etc.

Summarizing, the flow of the liquid cooling agent is as follows. The fluid pump pumps the liquid cooling agent through the first cooling agent tube 28 and the first fluid port 26 into the RF air coil 16. The liquid cooling agent flows through the RF air coil 16, wherein heat generated during the operation of the RF air coil is transferred into the liquid cooling agent. The heated liquid cooling agent flows through the second fluid port 32 and the second cooling agent tube 34 to the heat sink 36, where the heat is dissipated from the liquid cooling agent. Afterwards, the cooled liquid cooling agent flows back into the reservoir.

It will be appreciated that any suitable type of liquid cooling agent may be used. For example, the liquid cooling agent may be deionized water.

FIG. 2 shows a perspective view of a portion of the electrical circuit system 10 described above. As is illustrated in FIG. 2, the RF air coil 16 comprises a first hollow conductor 38 that has a first end portion 40 and a second end portion 42. Between the first end portion 40 and the second end portion 42, the first hollow conductor 38 extends in a coil shape.

The RF air coil 16 further comprises a second hollow conductor 44 that has a first end portion 46 and a second end portion 48. Like the first hollow conductor 38, the second hollow conductor 44 extends in a coil shape between the first end portion 46 and the second end portion 48.

In an embodiment, the first hollow conductor 38 and the second hollow conductor 44 extend directly adjacent to each other between the first end portions 40, 46 and the second end portions 42, 48.

The first hollow conductor 38 and the second hollow conductor 44 form, for example, the winding(s) of the RF air coil 16.

In general, the RF air coil 16 has at least one winding. In the example embodiment shown in FIG. 2, the RF air coil 16 comprises a plurality of windings formed by the hollow conductors 38, 44.

As is further illustrated in FIG. 2, the first fluid port 26 is fluidly connected to the first end portion 40 of the first hollow conductor 38, such that the liquid cooling agent can flow from the first fluid port 26 into the first end portion 40, and through the first hollow conductor 38 to the second end portion 42 of the first hollow conductor.

At the second end portions 42, 48, a redirecting portion 50 is provided that is a separate component from the hollow conductors 38, 44. The redirecting portion is fluidly connected to both second end portions 42, 48.

In general, the redirecting portion 50 is configured to redirect the liquid cooling agent from the second end portion 42 of the first hollow conductor 38 to the second end portion 48 of the second hollow conductor 44. Thus, the liquid cooling agent flows from the second end portion 42 of the first hollow conductor 38 through the redirecting portion 50 into the second end portion 48 of the second hollow conductor 44.

From the second end portion 48 of the second hollow conductor 44, the liquid cooling agent flows through the second hollow conductor 44 to the first end portion 46 and into the second fluid port 32, which is fluidly connected to the first end portion 46 of the second hollow conductor 44.

In the example embodiment shown in FIG. 2, the redirecting portion 50 simultaneously provides the at least one second electrical contact 22.

In an embodiment, the redirecting portion 50 may have a housing 51 that is made of a conductive material, for example of a metal such as copper, wherein the housing 51 comprises or is attached to the at least one second electrical contact 22.

The at least one first electrical contact 18 may be established by a housing portion 52 that accommodates the fluid ports 26, 32. For example, the housing portion 52 may be made of a metal such as copper. Alternatively, the at least one first electrical contact 18 may be provided by attaching at least one wire to the first end portions 40, 46, e.g. by soldering. Likewise, the at least one second electrical contact 22 may be provided by attaching at least one wire to the second end portions 42, 48, e.g. by soldering.

As is further illustrated in FIG. 2, the RF air coil 16 may further comprise a stiffening element 53 that is inserted within the windings of the RF air coil 16. In an embodiment, the stiffening element 53 abuts the individual windings of the RF air coil 16, thereby stabilizing the form of the RF air coil 16.

In an embodiment, the stiffening element 53 may comprise indentations through which the hollow conductors 38, 44 extend, such that the position of the hollow conductors 38, 44 is stabilized by the indentations.

In the example embodiment shown in FIG. 2, the stiffening element 53 has a plate shape. However, it is to be understood that the stiffening element 53 may have any other suitable shape.

The stiffening element 53 may consist (essentially) of or comprise any suitable form-stable and electrically insulating material.

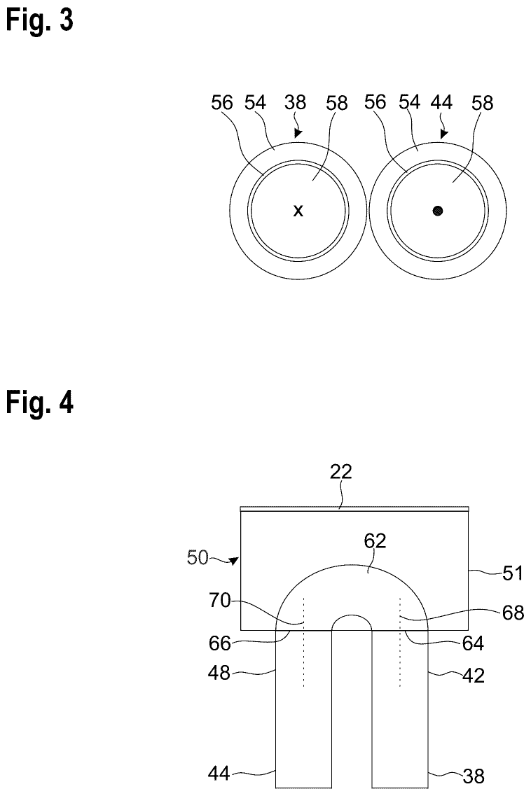

FIG. 3 schematically shows a cross section through a middle section of the RF air coil 16. As is illustrated in FIG. 3, the hollow conductors 38, 44 each comprise a conductive layer 54, e.g. a wall, for example a radially outer wall.

In an embodiment, the conductive layer 54 may comprise or consist (essentially) of any suitable electrically conductive material. Therein, an electrically conductive material may be chosen that has both high electrical conductivity and thermal conductivity.

For example, the electrically conductive material may comprise at least one electrically conductive metal. In an embodiment, a metal or metal alloy having both high electrical conductivity and thermal conductivity may be used, for example copper.

As another example, the at least one electrically conductive material comprises at least one electrically conductive non-metallic material, wherein a non-metallic material or combination of materials having both high electrical conductivity and thermal conductivity may be used.

Therein, the at least one electrically conductive non-metallic material is diamagnetic or paramagnetic. Accordingly, the at least one electrically conductive non-metallic material is not ferromagnetic, and has low magnetic permeability.

In an embodiment, the conductive layer 54 may have at least a predetermined thickness, for example at least five times the skin depth of an RF signal having the lowest frequency (corresponding to the highest skin depth) to be processed by the electrical circuit 12.

Optionally, a protective layer 56 may be provided on the inner surface of the conductive layer 54. Therein, the protective layer 56 may be coated onto the conductive layer 54, e.g. from the inside. Alternatively, the protective layer 56 may be provided first, and the conductive layer 54 may be coated onto the protective layer 56.

In general, a material having chemical resistance to the cooling agent to be used may be chosen for the protective layer 56. Further, a material having high thermal conductivity may be chosen for the protective layer 56. For example, the protective layer 56 comprises at least one of plastic, stainless steel, or lacquer. However, it is to be understood that any other suitable type of material may be used for the protective layer 56.

In an embodiment, the hollow conductors 38, 44 each have a hollow interior 58 that is confined by the conductive layer 54 or, if present, by the protective layer 56. The liquid cooling agent flows through this hollow interior 58, as is indicated by the dots and “x”.

In the example embodiment shown in FIGS. 2 and 3, the hollow conductors 38, 44 each have a circular cross section. However, it is to be understood that the hollow conductors 38, 44 may have any other suitable type of cross section, e.g. a rectangular cross section, a quadratic cross section, a hexagonal cross section, an elliptic cross section, etc.

In an embodiment, the cross sections of the hollow conductors 38, 44 may be constant at least piece-wise, e.g. at least for the portions of the hollow conductors 38, 44 forming the windings of the RF air coil 16. In an embodiment, the cross sections of the hollow conductors 38, 44 may be constant along their entire length, which provides particularly optimal flow conditions for the liquid cooling agent.

In an embodiment, the cross section of the first hollow conductor 38 may be equal to the cross section of the second hollow conductor 44. However, it is also conceivable that the cross sections of the hollow conductors 38, 44 may be different from each other.

FIG. 4 schematically shows a cross section through the end portions 42, 48 and the redirecting portion 50, which corresponds to the embodiment illustrated in FIG. 2. The redirecting portion 50 or the housing 51 of the redirecting portion 50 comprises a fluid canal 62 for redirecting the liquid cooling agent from the second end portion 42 of the first hollow conductor 38 to the second end portion 48 of the second hollow conductor 44.

Simultaneously, the housing 51 provides the at least one second electrical contact 22.

For example, the fluid canal 62 may be milled or forged into the housing 51, or the housing may be formed with the fluid canal 62 at the outset.

In an embodiment, the cross section of the fluid canal 62 may match the cross sections of the hollow conductors 38, 44.

In an embodiment, the second end portion 42 of the first hollow conductor 38 comprises an opening 64 that is connected to the fluid canal 62. Likewise, the second end portion 48 of the second hollow conductor 44 comprises an opening 66 that is connected to the fluid canal 62.

In an embodiment, the end portions 42, 48 are parallel to each other, i.e. the second end portion 42 of the first hollow conductor 38 has an axial axis 68 that is parallel to an axial axis 70 of the second end portion 48 of the second hollow conductor 44.

Thus, the redirecting portion 50 or the fluid canal 62 provides a 180° redirection for the liquid cooling agent.

According to an alternative embodiment, the redirecting portion 50 may be a tube that is separate from the hollow conductors 38, 44. For example, the tube may comprise or consist (essentially) of a metal or a plastic, such as PEEK, PEK, PPS, PI, PEI, etc. It is easier to connect the hollow conductors 38, 44 with the redirecting portion 50 in case the tube comprises or consists of a metal.

It is to be understood that the redirecting portion 50 may be established in any other suitable way.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described according to one or more embodiments can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A radio frequency (RF) air coil, comprising:
a first hollow conductor and a second hollow conductor that each comprise an electrically conductive material, wherein the first hollow conductor and the second hollow conductor form at least one winding of the RF air coil,
the first hollow conductor has a first end portion and a second end portion,
the second hollow conductor has a first end portion that is arranged adjacent to the first end portion of the first hollow conductor and a second end portion that is arranged adjacent to the second end portion of the first hollow conductor,
a first fluid port fluidly connected to the first hollow conductor and a second fluid port fluidly connected to the second hollow conductor such that a liquid cooling agent can flow through the first fluid port, the first hollow conductor, the second hollow conductor, and the second fluid port,
wherein the first hollow conductor and the second hollow conductor provide two separate fluid path portions for the liquid cooling agent, and
wherein the first fluid port is arranged at the first end portion of the first hollow conductor and the second fluid port is arranged at the first end portion of the second hollow conductor.

2. The RF air coil of claim 1, wherein the electrically conductive material comprises at least one electrically conductive metal.

3. The RF air coil of claim 2, wherein the at least one electrically conductive metal comprises copper.

4. The RF air coil of claim 1, wherein the at least one electrically conductive material comprises at least one electrically conductive non-metallic material.

5. The RF air coil of claim 1, wherein the electrically conductive material is arranged at a radially outer portion of the hollow conductors.

6. The RF air coil of claim 1, further comprising a redirecting portion that fluidly connects the second end portion of the first hollow conductor with the second end portion of the second hollow conductor.

7. The RF air coil of claim 6, wherein the redirecting portion is formed separately from the first hollow conductor and the second hollow conductor.

8. The RF air coil of claim 7, wherein the redirecting portion comprises a housing being formed separately from the first hollow conductor and the second hollow conductor.

9. The RF air coil of claim 7, wherein the redirecting portion comprises a tube that is separate from the hollow conductors.

10. The RF air coil of claim 1, wherein at least the portions of the first hollow conductor and the second hollow conductor forming the at least one winding extend directly adjacent to each other.

11. The RF air coil of claim 1, wherein a cross section of the first hollow conductor is constant at least piecewise, and/or wherein a cross section of the second hollow conductor is constant at least piecewise.

12. The RF air coil of claim 1, further comprising at least one first electrical contact for the first end portions.

13. The RF air coil of claim 1, wherein the RF air coil comprises at least one second electrical contact for the second end portions.

14. The RF air coil of claim 1, wherein inner surfaces of walls of the hollow conductors each comprise a protective layer.

15. The RF air coil of claim 14, wherein the protective layer comprises at least one of plastic, stainless steel, or lacquer.

16. An electrical circuit system, comprising
an electrical circuit;
a heat sink;
a first cooling agent tube; a second cooling agent tube; and
an RF air coil system, wherein the RF air coil system comprises an RF air coil according to claim 1,
wherein the first cooling agent tube is connected to the first fluid port of the RF air coil, wherein the second cooling agent tube is connected to the second fluid port of the RF air coil, and wherein at least one of the first cooling agent tube or the second cooling agent tube is directly connected to the heat sink.

17. The electrical circuit system of claim 16, wherein the first cooling agent tube and the second cooling agent tube each comprise an electrically isolating material at least partially.

18. The electrical circuit system of claim 16, further comprising at least one electrical isolator, wherein the at least one electrical isolator is configured to electrically isolate the hollow conductors from the heat sink.

19. The electrical circuit system of claim 16, wherein the electrical circuit is at least one of an oscillating circuit, an impedance matching circuit, an RF filter circuit, an RF antenna circuit, or an RF frontend circuit.
